(19) United States
(12) Patent Application Publication
(10) Pub. No.: US 2018/0286946 A1
(43) Pub. Date: Oct. 4, 2018

(54) NOVEL STI PROCESS FOR SDB DEVICES

(71) Applicant: GLOBALFOUNDRIES, Inc., Grand Cayman (KY)

(72) Inventor: Shesh Mani Pandey, Saratoga Springs, NY (US)

(21) Appl. No.: 15/967,156

(22) Filed: Apr. 30, 2018

Related U.S. Application Data
(63) Continuation of application No. 15/195,988, filed on Jun. 28, 2016, now abandoned.

(51) Int. Cl. H01L 29/06; H01L 29/417; H01L 29/66; H01L 21/8234; H01L 27/088

(52) U.S. Cl. CPC H01L 29/0653; H01L 29/41791; H01L 29/66545; H01L 27/0886; H01L 21/823481; H01L 21/823431

(57) ABSTRACT

A shallow trench isolation (STI) structure is formed having a conventional STI trench structure formed of dielectric material extending into the substrate. A planarizing stack of nitride and oxide is formed above the STI trench structure (and optionally a dummy gate may be formed above this stack). After further conventional processing, the nitride layer results in a structure that extends laterally outward beyond the outer edges of the underlying STI structure—creating a shadow or umbrella structure. The S/D cavity is formed (between the active gate and dummy gate) and the epitaxial S/D regions are grown. The placement and configuration of the nitride layer assists in reducing the amount of substrate material removed adjacent the STI structure during the S/D region cavity formation.

### CROSS-REFERENCE TO RELATED APPLICATIONS

This application is a continuation of U.S. patent application Ser. No. 15/195,988 filed Jun. 28, 2016, the disclosure of which is hereby incorporated by reference in its entirety.

### TECHNICAL FIELD

The present disclosure relates generally to the manufacture of semiconductor devices, and more particularly, to the fabrication and manufacture of a novel shallow trench isolation (STI) process and structure for use with field-effect transistor (FET) type structures.

### BACKGROUND

Single diffusion break (SDB) devices are becoming more desirable due to their improved performance capabilities. However, the present performance of such devices is mainly affected by the resulting shape of the epi source/drain regions. This shape impacts contact resistance, device drive current and leakage current.

As shown in FIG. 1A, a prior art device 10 includes a dummy gate 12 covering a shallow isolation trench 14 between a pair of neighboring FinFETs 16A, 16B (each only partially shown) providing a single diffusion break. Prior art device 10 is also shown with an epitaxial source/drain (S/D) region 18 (for FET 16A) and S/D region 20 (for FET 16B) formed within a substrate 22. Spacers 24 are formed along FinFETs 16A, 16B and the dummy gate 12.

However, patterning for the shallow isolation trench 14 is difficult at small dimensions using conventional lithography and etch techniques presently available. The prior art device 10 may suffer from leakage between the S/D through the dummy gate 12.

More importantly, as shown in FIG. 1B, after cavity etching, the epitaxy (epi) of the S/D regions 18, 20 grows non-ideally resulting in asymmetric growth and a shape that degrades performance. This growth typically results in a slanted epi S/D region slanting downward toward the isolation trench 14 because there is little (if any) substrate 22 available for growth adjacent the isolation trench 14. Because of the small dimensions, the cavity etch for the S/D regions etches away most of the substrate 22 near the isolation trench 14. In addition, the device 10 still provides a potential leakage path through the dummy gate 12.

Accordingly, there is a need for a new trench isolation structure (and methods of manufacture/fabrication) that enables a growth of more uniform epitaxial S/D regions to improve active device performance.

### SUMMARY

In accordance with one advantageous embodiment, there is provided a semiconductor device having a shallow trench isolation (STI) structure disposed within a semiconductor substrate. The STI structure includes a first STI layer disposed in the substrate and having sidewalls, and an STI protective layer disposed in the substrate and above the STI layer, the STI protective layer extending laterally outward and beyond the sidewalls. A field effect transistor (FET) disposed on the semiconductor substrate and having a gate structure, an epitaxial first source/drain (S/D) region, and an epitaxial second S/D region, wherein the epitaxial first S/D region is disposed adjacent to the STI structure.

In another embodiment, there is provided a method of manufacturing or fabricating a semiconductor device for use with one or more field-effect transistor (FinFET) devices. The method includes forming a shallow trench isolation (STI) structure within a semiconductor substrate, which includes forming a trench in the substrate and depositing first insulating material in the shallow trench, forming a wider and shallower second trench within the substrate and above the first insulating material to expose at least a portion of the first insulating material, and forming a protective layer within the substrate and above the first insulating material. The method also includes forming a field effect transistor (FET) disposed on the substrate and having a gate structure, an epitaxial first source/drain (S/D) region, and an epitaxial second S/D region, wherein the epitaxial first S/D region is formed adjacent to the STI structure.

In yet another embodiment, there is provided a method of fabricating a semiconductor device for use with one or more field-effect transistor (FET) devices. The method includes forming a shallow trench isolation (STI) structure within a semiconductor substrate by forming first insulating material in a shallow trench within the substrate, forming a protective layer within the substrate and above the first insulating material, the protective layer extending laterally beyond a side of the first insulating material in the shallow trench, and forming second insulating material above the protective layer. A dummy gate structure is formed above and aligned with the STI structure, and the dummy gate structure has a first sidewall and a second sidewall. A first field effect transistor (FET) is formed on the substrate, and the first FET includes a gate structure adjacent the dummy gate structure, a first source/drain (S/D) region and a second S/D region, wherein the first S/D region is formed adjacent to the STI structure, and the protective layer of the STI structure extends into the first source/drain region and extends laterally outward beyond a sidewall of the dummy gate structure. Selected portions of the first S/D region are removed such that a portion of the first S/D region underneath the protective layer remains (is protected from removal), and the first S/D region is further epitaxially grown and formed.

The foregoing has outlined rather broadly the features and technical advantages of the present disclosure so that those skilled in the art may better understand the detailed description that follows. Additional features and advantages of the present disclosure will be described hereinafter that form the subject of the claims. Those skilled in the art should appreciate that they may readily use the concept and the specific embodiment(s) disclosed as a basis for modifying or designing other structures for carrying out the same or similar purposes of the present disclosure. Those skilled in the art should also realize that such equivalent constructions do not depart from the spirit and scope of the claimed invention in its broadest form.

Before undertaking the Detailed Description below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior uses, as well as future uses, of such defined words and phrases.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIGS. 1A and 1B illustrate a cross-sectional view of two FinFET-type semiconductor devices in accordance with the prior art;

FIG. 2 illustrates a cross-sectional view of three FinFET-type semiconductor devices in accordance with the present disclosure;

FIG. 3 is a more detailed and expanded partial cut-away view of the STI structure and S/D region interface in accordance with the present disclosure; and

FIGS. 4-8 are diagrams that illustrate a series of steps of one embodiment of a method or process for manufacturing the FinFET-type devices shown in FIG. 2.

### DETAILED DESCRIPTION

The present disclosure describes a novel STI structure (and method of forming) for use with FET-type semiconductor devices. The STI structure includes a conventional trench structure formed of dielectric material extending into the substrate. A planarizing stack of nitride and oxide is formed above the STI structure (and optionally a dummy gate may be formed above this stack). After further conventional processing, the nitride layer results in a structure that extends outward beyond the outer edges of the underlying STI structure—creating a shadow or umbrella structure (or overhang structure). The S/D cavity is formed (between the active gate and dummy gate) and the epi S/D regions are grown. The placement and configuration of the nitride layer assists in reducing the amount of substrate material removed adjacent the STI structure during the S/D region cavity formation. Hence, S/D region epi growth is more uniform and level.

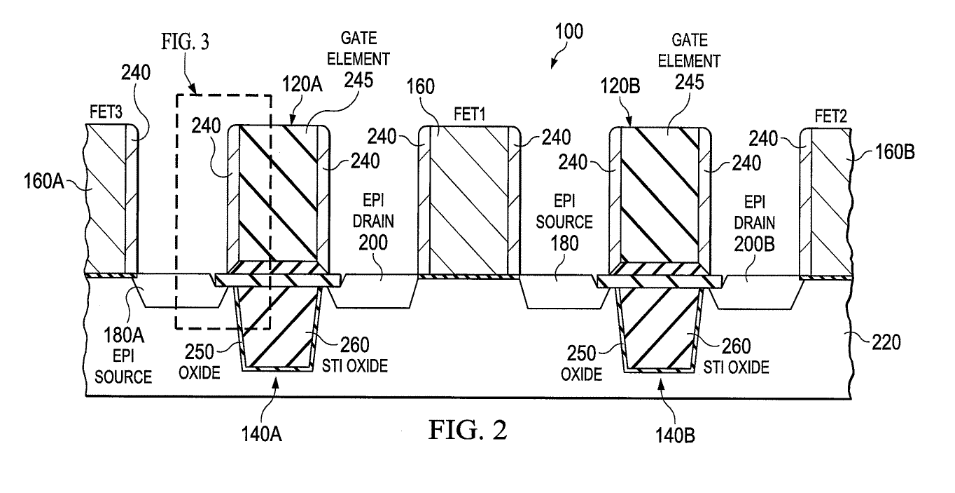

FIGS. 2 through 8 and the various embodiments used to describe the principles of the present disclosure in this patent document are by way of illustration only and should not be construed in any way to limit its scope. Those skilled in the art will understand that the principles described herein may be implemented in any type of suitably arranged FET device.

To simplify the drawings, reference numerals from previous drawings will sometimes not be repeated for structures that have already been identified.

Now turning to FIG. 2, there is shown a semiconductor device 100 having a semiconductor substrate 220 and including a pair of dummy gates 120A, 120B disposed above a pair of shallow trench isolation (STI) structures 140A, 140B each providing a single diffusion break. A FinFET device 160 is disposed between the STI structures 140A, 140B which provide isolation for the FinFET device 160. Also shown is a pair of neighboring FinFETS 160A and 160B (each only partially shown). The FinFET 160 is shown with epitaxial source/drain (S/D) regions 180, 200 formed in the substrate 220. Similarly, although only partially shown, the FinFETs 160A, 160B each have two epitaxial S/D regions (and only source region 180A and drain region 200B are shown). Further, only the relevant portions of the FinFET devices 160, 160A, 160B are shown, and the source and drain contacts (and actual gate contacts) are not illustrated.

It will also be understood that, depending on the type of FET device desired, S/D regions 180, 200 will be doped with either n-type or p-type impurities, while their corresponding channel regions (in the substrate 220) may be doped with the opposite type—either p-type or n-type (or no type), respectively.

For ease of reference, the following description will be in reference to the STI structure 140A (disposed between and isolating the FinFET 160 from the FinFET 160A) and its associated dummy gate structure 120A. The STI structure 140A includes a thin layer of oxide 250 and an STI oxide structure/layer or other insulating material 260. A protective layer of nitride 270 is disposed above the STI oxide structure 260 (and the oxide layer 250) and extends (laterally) beyond the outer edge(s) of the STI oxide structure 260 as shown.

In one embodiment, the protective nitride layer 270 extends beyond the outer edge may be in the range of about 5 to 35 nanometers or 5 to 25 nanometers, and in another embodiment is about 10 nm or more. This results in the nitride layer 270 above the STI oxide structure 260 that provides a shadowing mask or overhanging structure to protect the substrate adjacent STI oxide structure. As will be appreciated, the nitride layer 270 additionally extends outward beyond the outer surfaces of the sidewall spacer(s) of the gate structure. In another embodiment, the nitride layer 270 extends beyond the outer edge of the sidewall(s) of the gate structure about 5 nanometers or more, and in another embodiment, extends between about 5 to 20 nm. As will be described further below, after formation, the nitride layer 270 functions to substantially protect the substrate 220 (underneath the nitride layer 270) from being etched away during certain processing steps—providing an etch stop when etching/removing the substrate in the areas of the S/D regions. Disposed above the nitride layer 270 is another layer of oxide or other insulating material 280.

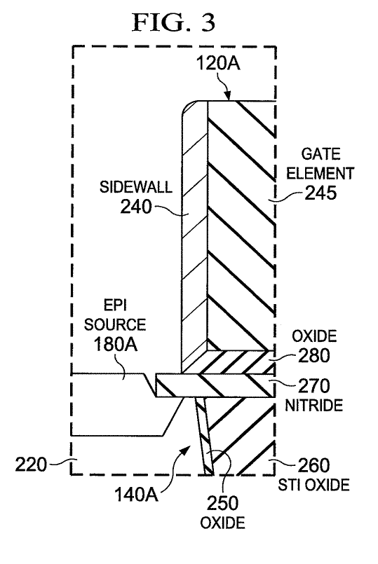

The dummy gate structure 120A includes sidewall spacers 240 and a gate element 245. The gate element 245 may be formed of any suitable insulating material, and may be formed of conductive material such as polysilicon. Now turning to FIG. 3, there is shown a more detailed and expanded partial cut-away view of the STI structure 140A, dummy gate structure 120A and the source region 180A. As will be appreciated, this structure will be similar in configuration on the STI structure 140A near the drain region 200 (and will be similar for the other STI structure 140B).

As will be appreciated, the addition of the nitride layer 270, shown in FIGS. 2 and 3, provides an etch stop or protective barrier that protects the semiconductor substrate 220 underneath the nitride layer 270 from being etched/removed during cavity formation prior to epitaxial growth and formation of the S/D regions 180, 200.

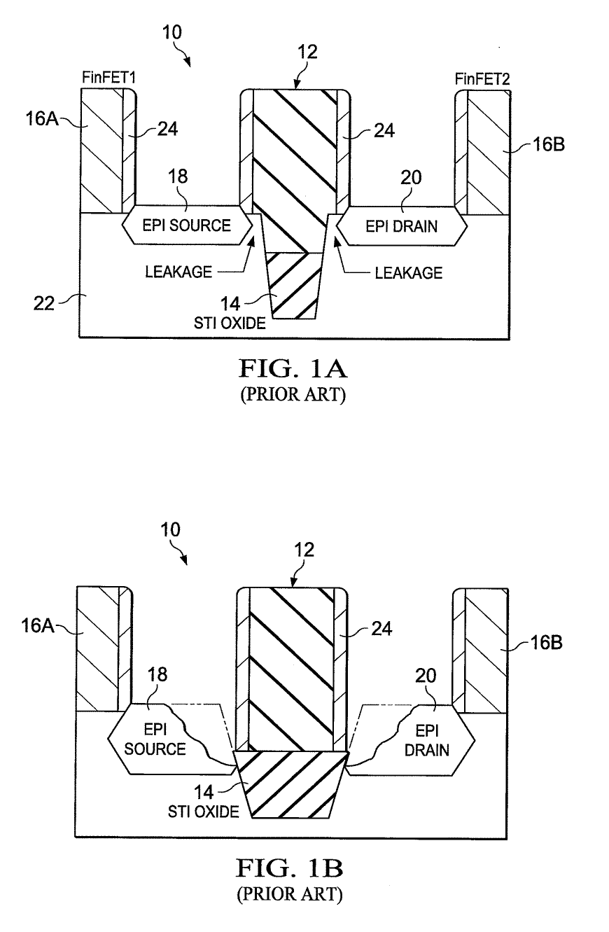

Now turning back to FIG. 1B, during formation of the epitaxial S/D regions 18, 20 of the prior art device, after formation of the STI structures, gate structures (both active and dummy) and planarization, a cavity is formed through insulating material (shown as already removed) between the sidewalls that extends down to the substrate 22. As shown, the cavity etch removes most (or all) of the substrate 22 along the vertical walls of the STI oxide 14. After cavity formation, the epitaxial S/D regions are formed by an epitaxial growth process. In this case, as noted earlier, this growth typically results in a slanted epitaxial S/D region slanting downward toward the isolation trench 14 because there is little (if any) substrate 22 available for growth adjacent the isolation trench 14. Because of the small dimensions, the cavity etch for the S/D regions etches away most of the substrate 22 near the isolation trench 14. As noted, this degrades performance.

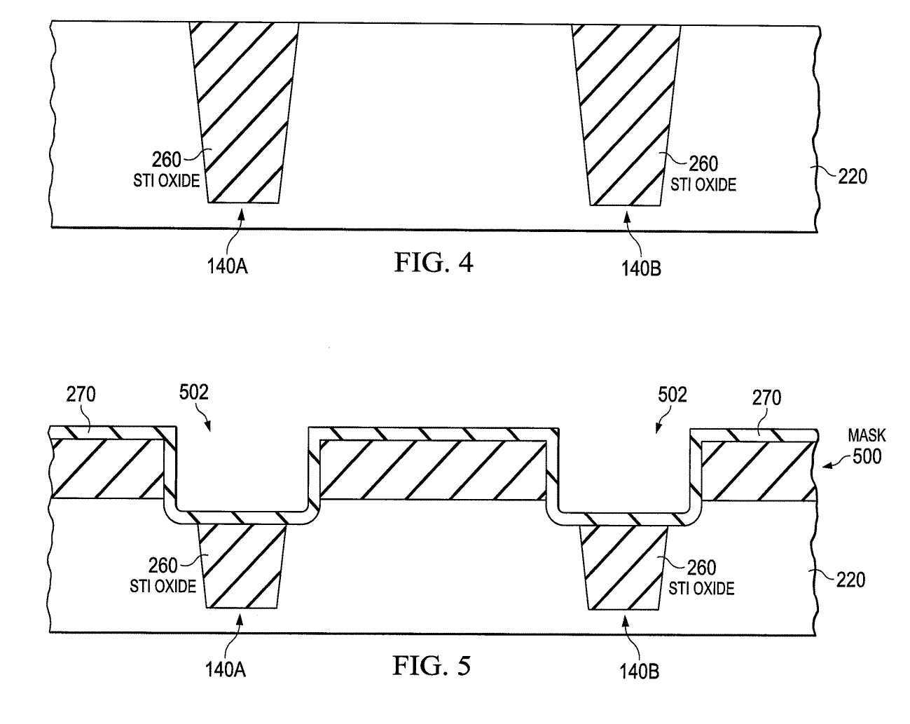

FIGS. 4 through 8 are diagrams that illustrate a series of relevant steps of one embodiment of a method or process for manufacturing the semiconductor device 100, including the FinFET devices 160, 160A, 160B (shown in FIG. 2).

Now turning to FIG. 4, the semiconductor substrate 220 is provided and formed with STI structures 260 disposed therein. To form the structure shown in FIG. 4, a mask (not shown) formed above the substrate 220 is used with an etching/removal process that selectively removes portion(s) of substrate at the desired location(s) to form “shallow” trenches. Any suitable mask material may be used (e.g., nitride, oxide/nitride stack, photoresist material, etc.). The trenches are filled with material using a suitable process to form the STI oxide structures 260 of the STI structures 140A, 140B, and if necessary, planarization and mask removal occurs—resulting in the structure shown in FIG. 4.

The substrate 220 may be any suitable substrate material, such as bulk or epitaxially grown semiconductor material (e.g., silicon, silicon compounds) or silicon-on-insulator (SOI). The STI oxide structures 260 may be formed of any suitable material providing insulating and/or isolating functions, such as silicon oxide. Though not shown in FIG. 4 (but shown in FIG. 3), a thin layer of oxide 250 may be formed within the trenches prior to formation of the STI oxide structures 260.

Now turning to FIG. 5, the structure shown in FIG. 4 undergoes a masking and etching process (not shown in detail) which selectively opens a wider portion above the STI oxide structures 260. A mask 500, such as a nitride mask, is formed with openings coincident with the STI structures, yet wider in area. Selective portions of the substrate 220 along with a top portion of the STI oxide structures 260 are etched/removed—leaving a wider valley or depression formed above the structures 260 and into the substrate 220. After the removal process, the protective layer 270 is formed above the STI trenches, portion(s) of the substrate 220 and the mask 500—as shown.

The protective layer 270 may be any suitable material, and preferably is a material that resists a later etching/removal process that will occur during the cavity formation when forming the epitaxial S/D regions. In one embodiment, the protective layer 270 is a nitride layer. In other embodiments, the nitride layer has a thickness in the range of 5 to 25 nanometers (nm), and in another embodiment is about 10 nm. Once the protective layer 270 is formed—as shown in FIG. 5—the resulting structure includes wider and shallower trenches (depicted by reference numerals 502) above the STI oxide structures 260.

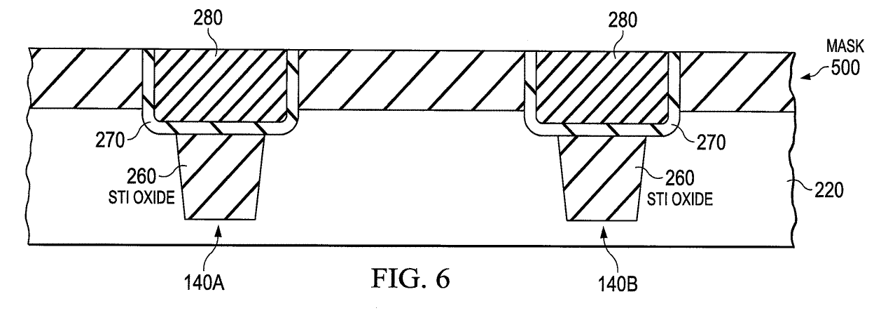

Now turning to FIG. 6, the structure shown in FIG. 5 undergoes a fill and planarization process that fills the remaining trenches with insulating material and planarizes the to structure. A suitable insulating layer or material 280, such as oxide, is formed or deposited in the trenches and above the protective layer 270. The structure is then planarized, using a suitable planarization process, such as by chemical-mechanical polishing (CMP). This process removes portions of the layer 280, the layer 270 and the mask layer 500. The resulting planarized structure is shown in FIG. 6. As will be appreciated, the STI oxide structure 260, the protective layer 270 thereabove, and a portion of the oxide layer 280 together will form the STI structures 140A, 140B.

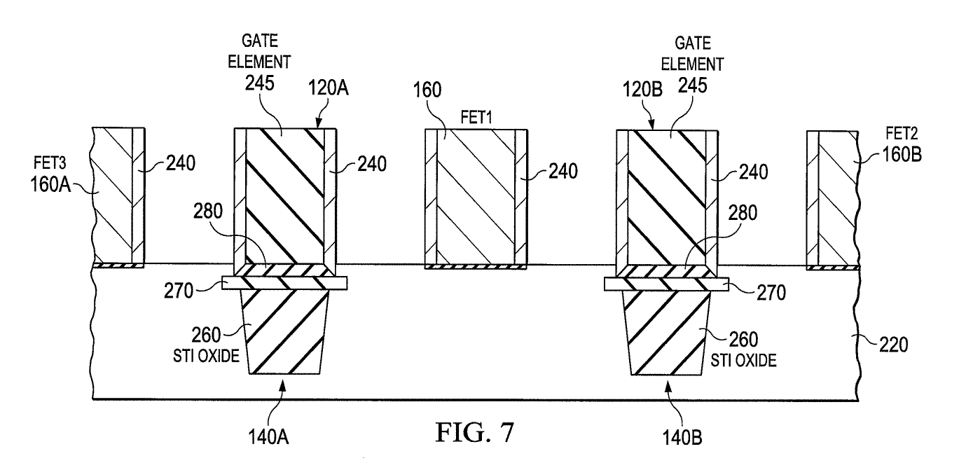

Now turning to FIG. 7, further processing of the structure shown in FIG. 6 includes forming the dummy gate structures 120A, 120B above STI structures 140A, 140B. The active gate structures 160, 160A, 160B are also formed above the substrate 220, and as shown, the active gate structure is formed between the adjacent STI structures 140A and 140B.

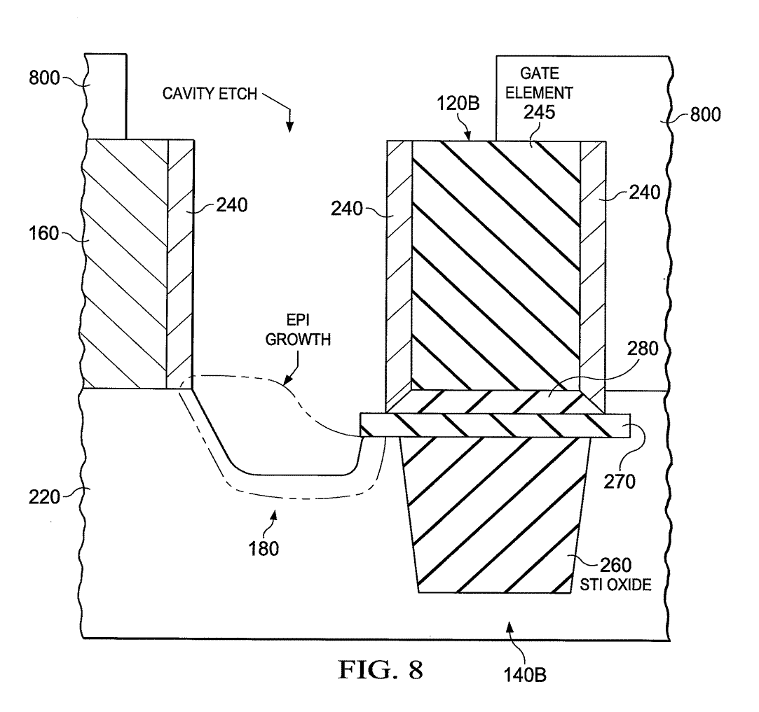

After this processing, the structure shown in FIG. 7 undergoes S/D region formation. An S/D mask 800 is formed above the gate structures with openings that selectively enable formation of the S/D regions. Thus, a cavity or opening to S/D region areas 180, 200 is provided by the S/D mask 800 and the sidewalls of the adjacent gate structure(s). To illustrate this process, a partial view of a portion of the structure shown in FIG. 7 is shown in FIG. 8. As shown, selected S/D regions are exposed per the S/D mask configuration (e.g., cavity etch) which creates openings (or windows) to the S/D regions 180, 200. In FIG. 8, this is shown specifically relative to the S/D region 180 of the FinFET 160.

As the cavity/opening process (cavity etch) progresses, the selected portion(s) of the substrate 220 are removed. The process continues until a desired portion of the substrate 220 is removed—as shown in FIG. 8. After the S/D cavity etch process, the S/D region 180 is formed by epitaxial growth of the exposed silicon substrate 220. As shown, the S/D region 180 epitaxially grows into an S/D region illustrated by the dotted lines (and naturally consumes silicon as part of the growth process).

Because the portion of the silicon substrate 220 that lies beneath the protective layer 270 is protected or otherwise not removed during the S/D cavity etch, a substantial amount of silicon substrate 220 remains between the cavity and the STI structure 140B. This enables a more uniform epitaxial S/D region to form. As shown, the protective layer 270 extends laterally beyond the outer sides (spacers 240) of the dummy gate structure 120A and results in a larger lateral dimension between the cavity and the STI oxide structure 260. In other words, after S/D cavity etch, the cavity wall in the substrate 220 is spaced further from the STI structure 140B. The more uniform growth and structural configuration of the epitaxial S/D region 180 enhances performance.

Once the S/D regions 180, 200 are formed, each may be doped as desired. As will be appreciated, further processing of the semiconductor device 100 is not shown.

While FIG. 4-8 show relevant steps in one embodiment of forming the various components of the device 100, additional conventional/typical semiconductor manufacturing processes generally follow (which are not described herein, and is unnecessary for the understanding of the teachings herein). Further, not all processing steps may be shown—only those relevant to the understanding of the present disclosure.

It will be understood that the present disclosure may be embodied in many different forms and should not be construed as limited to the exemplary embodiments set forth herein. Terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. The terms “comprises” and/or “comprising”, or “includes” and/or “including”, when used in this specification, specify the presence of stated features, regions, structures, elements, and/or components, but do not preclude the presence or addition of one or more other of these. Reference throughout this specification to “one embodiment,” “an embodiment,” “embodiments,” “exemplary embodiments,” or similar language means that a particular feature, structure, or characteristic described in connection with the embodiment is included in at least one embodiment of the present disclosure.

If used, the terms “overlying” or “atop”, “positioned on” or “positioned atop”, “underlying”, “beneath” or “below” mean that a first element, such as a first structure, e.g., a first layer, is present on a second element, such as a second structure, e.g., a second layer, wherein intervening elements, such as an interface structure, e.g. interface layer, may be present between the first element and the second element.

As used herein, “depositing” or “forming” may include any now known or later developed techniques appropriate for the material to be deposited or formed including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UH-VCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer 20 deposition (ALD), chemical oxidation, molecular beam epitaxy (MBE), plating, evaporation.

It will be understood that well known processes have not been described in detail and have been omitted for brevity. Although specific steps, structures and materials may have been described, the present disclosure may not limited to these specifics, and others may substituted as is well understood by those skilled in the art, and various steps may not necessarily be performed in the sequences shown.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

1. A semiconductor device comprising:
a semiconductor substrate;
a shallow trench isolation (STI) structure disposed within the semiconductor substrate, the STI structure comprising:
a first STI layer disposed in the substrate and having a first sidewall and a second sidewall, and
an STI protective layer disposed in the substrate and above the first STI layer, the STI protective layer extending laterally outward and beyond at least one of the first and second sidewalls; and
a field effect transistor (FET) disposed on the semiconductor substrate and having a first gate structure, an epitaxial first source/drain (S/D) region, and an epitaxial second S/D region, wherein the epitaxial first S/D region is disposed adjacent to the STI structure.

2. The device in accordance with claim 1 wherein the STI structure further comprises:
a second STI layer disposed above the STI protective layer.

3. The device in accordance with claim 1 wherein the STI protective layer comprises nitride.

4. The device in accordance with claim 3 wherein the STI protective layer has a thickness between about 5 and 25 nanometers.

5. The device in accordance with claim 1 wherein the STI protective layer extends laterally outward beyond one of the first and second sidewalls of the first STI layer at least about 5 to 25 nanometers.

6. The device in accordance with claim 5 wherein the STI protective layer extends laterally outward at least about 10 nanometers.

7. The device in accordance with claim 1 further comprising:
a dummy gate structure disposed above the STI structure and adjacent the first gate structure, the dummy gate structure comprising a first sidewall and a second sidewall, wherein the STI protective layer extends laterally outward beyond at least one of the first and second sidewalls of the dummy gate structure at least about 5 nanometers.

8. The device in accordance with claim 7 wherein the STI protective layer extends laterally outward beyond both the first sidewall and the second sidewall of the dummy gate structure at least about 5 nanometers.

9. The device in accordance with claim 1 wherein the STI protective layer comprises nitride having a thickness between about 5 and 25 nanometers, and wherein the STI protective layer extends laterally outward beyond at least one of the first and second sidewalls of the first STI layer at least about 5 to 25 nanometers.

10. A method of fabricating a semiconductor device for use with one or more field-effect transistor (FinFET) devices, the method comprising:
forming a shallow trench isolation (STI) structure within a semiconductor substrate, comprising,
forming a trench in the substrate and depositing first insulating material in the shallow trench,
forming a wider and shallower second trench within the substrate and above the first insulating material to expose at least a portion of the first insulating material,
forming a protective layer within the second trench and above the first insulating material, and
forming a layer of second insulating material above the protective layer and within at least a portion of the second trench; and
forming a field effect transistor (FET) disposed on the substrate and having a gate structure, an epitaxial first source/drain (S/D) region, and an epitaxial second S/D region, wherein the epitaxial first S/D region is formed adjacent to the STI structure.

11. (canceled)

12. The method in accordance with claim 10 wherein the protective layer comprises nitride.

13. The method in accordance with claim 12 wherein the protective layer has a thickness between about 5 and 25 nanometers.

14. The method in accordance with claim 10 wherein the first insulating material within the first trench comprises a first sidewall and a second sidewall, and wherein the protective layer extends laterally outward beyond at least one of the first and second sidewalls at least about 5 to 25 nanometers.

15. The method in accordance with claim 10 further comprising:
forming a dummy gate structure disposed above the STI structure and adjacent the gate structure of the FET, the dummy gate structure comprising a first sidewall and a second sidewall, and wherein the protective layer extends laterally outward beyond at least one of the first and second sidewalls of the dummy gate structure at least about 5 nanometers.

16. The method in accordance with claim 15 wherein the protective layer extends laterally outward beyond both the first sidewall and the second sidewall of the dummy gate structure at least about 5 nanometers.

17. A method of fabricating a semiconductor device for use with one or more field-effect transistor (FET) devices, the method comprising:
forming a shallow trench isolation (STI) structure within a semiconductor substrate, comprising,
forming first insulating material in a first shallow trench within the substrate,
forming a second trench above the first insulating material and in the substrate, wherein the second trench is wider and shallower than the first trench, and forming a protective layer within the second trench and above the first insulating material, the protective layer extending laterally beyond a side of the first insulating material in the second shallow trench, and
forming second insulating material above the protective layer and within at least a portion of the second trench;
forming a dummy gate structure above and aligned with the STI structure, the dummy gate structure having a first sidewall and a second sidewall;
forming a first field effect transistor (FET) on the substrate, the first FET having a gate structure adjacent the dummy gate structure, a first source/drain (S/D) region and a second S/D region, wherein the first S/D region is formed adjacent to the STI structure, and the protective layer of the STI structure extends into the first source/drain region and extends laterally outward beyond a sidewall of the dummy gate structure;
removing selected portions of the first S/D region, wherein a portion of the first S/D region underneath the protective layer is protected from being removed; and
epitaxially growing and forming the first S/D region.

18. The method in accordance with claim 17 wherein the protective layer comprises nitride.

19. The method in accordance with claim 17 wherein the protective layer has a thickness between about 5 and 25 nanometers.

20. The method in accordance with claim 17 wherein the first insulating material within the shallow trench comprises a first sidewall and a second sidewall, and wherein the protective layer extends laterally outward beyond at least one of the first and second sidewalls at least about 5 to 25 nanometers.
